(19) United States
(12) Patent Application Publication
(10) Pub. No.: US 2024/0359937 A1
(43) Pub. Date: Oct. 31, 2024

(54) PLASTIC FILM RECOVERY DEVICE USING VORTEX

(71) Applicant: Samsung Electronics Co., Ltd., Suwon-si (KR)

(72) Inventors: Kwangsoon CHOI, Suwon-si (KR); Heejun HAM, Gunpo-si (KR); Kyunghan RYU, Gunpo-si (KR); Kyujae LEE, Gunpo-si (KR)

(21) Appl. No.: 18/768,856

(22) Filed: Jul. 10, 2024

Related U.S. Application Data
(63) Continuation of application No. PCT/KR2022/020991, filed on Dec. 21, 2022.

(30) Foreign Application Priority Data
Feb. 14, 2022 (KR) 10-2022-0019147
Feb. 23, 2022 (KR) 10-2022-0023755

(51) Int. Cl. B65H 23/24; H05K 13/04

(52) U.S. Cl. CPC B65H 23/24; H05K 13/0419

(57) ABSTRACT

A plastic film recovery device for recovering a cover plastic film of a reel tape supplied to a mounter is provided. The plastic film recovery device includes a first suction part transferring the cover plastic film, which has been separated from the reel tape and introduced into one end of the plastic film recovery device, to another end of the plastic film recovery device opposite to the one end, by forming internal pressure lower than external pressure, a transfer part including a first opening part, connected to the other end of the first suction part, through which the cover plastic film is introduced from the other end, and a second opening part through which the cover plastic film introduced through the first opening part flows out, a first nozzle disposed inside the transfer part and ejecting air in a first direction facing the second opening part, a discharge part connected to the second opening part in the first direction and discharging the cover plastic film transferred through the transfer part, and a plurality of holes forming a vortex inside the discharge part by being disposed inside the discharge part to have an inclination with respect to the first direction.

### CROSS-REFERENCE TO RELATED APPLICATION(S)

This application is a continuation application, claiming priority under § 365 (c), of an International application No. PCT/KR2022/020991, filed on Dec. 21, 2022, which is based on and claims the benefit of a Korean patent application number 10-2022-0019147, filed on Feb. 14, 2022, in the Korean Intellectual Property Office, and of a Korean patent application number 10-2022-0023755, filed on Feb. 23, 2022, in the Korean Intellectual Property Office, the disclosure of each of which is incorporated by reference herein in its entirety.

### BACKGROUND

### 1. Field

The disclosure relates to a plastic film recovery device using a vortex.

### 2. Description of Related Art

A surface mount technology (SMT) is a technology that mounts a surface mounted components (SMC) on a surface of a printed circuit board. The SMT may be implemented by a mounter that mounts components on the surface of the printed circuit board and soldering, and a feeder that supplies the SMC in a form of reel tape to the mounter. The reel tape may include a base on which the SMC are disposed and a cover plastic film attached to the base to protect the SMC.

The feeder may include a reel on which the reel tape is wound. The feeder may transfer the reel tape wound on the reel to the mounter. When the reel tape is transferred to the mounter, the SMC may be supplied to the mounter as the cover plastic film of the reel tape is taken off, and the cover plastic film taken off may be discharged to the outside of the mounter. A plastic film recovery device may recover the cover plastic film discharged from the mounter.

The above information is presented as background information only to assist with an understanding of the disclosure. No determination has been made, and no assertion is made, as to whether any of the above might be applicable as prior art with regard to the disclosure.

### SUMMARY

A plastic film recovery device may include a configuration for recovering a cover plastic film separated from a reel tape. The configuration for recovering the cover plastic film of the plastic film recovery device may require a separate configuration connected to each of a plurality of reel tapes, in order to recover the plurality of reel tapes. For example, the plastic film recovery device may include a roller that recovers the cover plastic film by winding and rotating a part of the cover plastic film. The roller may include a plurality of pins on which a plurality of cover plastic films are mounted.

Since the cover plastic film extends long in one direction, discharge of the cover plastic film may not be smooth when recovering the cover plastic film through the plastic film recovery device. For example, the plastic film may get tangled between rollers, or the plastic film itself may get tangled, discharge through the roller may not be smooth. When recovering the cover plastic film, malfunction and/or failure may occur due to tangle of the cover plastic film.

When recovering a plurality of cover plastic films through the plastic film recovery device, a process for the plurality of cover plastic films may be required. For example, before operating the plastic film recovery device, a process of mounting the plurality of cover plastic films one by one between the plurality of pins may be necessary.

Aspects of the disclosure are to address at least the above-mentioned problems and/or disadvantages and to provide at least the advantages described below. Accordingly, an aspect of the disclosure is to provide a plastic film recovery device using a vortex, which smoothly discharges plastic films by the vortex and simply recovers the plurality of plastic films.

Additional aspects will be set forth in part in the description which follows and, in part, will be apparent from the description, or may be learned by practice of the presented embodiments.

In accordance with an aspect of the disclosure, a plastic film recovery device for recovering a cover plastic film of reel tape supplied to a mounter is provided. The plastic film recovery device includes a first suction part transferring the cover plastic film, which has been separated from the reel tape and introduced into one end of the first suction part, to another end of the first suction part opposite to the one end, by forming internal pressure lower than external pressure, a transfer part including a first opening part, connected to the other end of the first suction part, through which the cover plastic film is introduced from the other end, and a second opening part through which the cover plastic film introduced through the first opening part flows out, a first nozzle disposed inside the transfer part and ejecting air in a first direction facing the second opening part, a discharge part connected to the second opening part in the first direction and discharging the cover plastic film transferred through the transfer part, and a plurality of holes ejecting air for forming a vortex inside the discharge part by being disposed inside the discharge part to have an inclination with respect to the first direction.

In accordance with another aspect of the disclosure, a plastic film recovery device for recovering a cover plastic film of reel tape supplied to a mounter is provided. The plastic film recovery device includes a first suction part transferring the cover plastic film, which has been separated from the reel tape and introduced into one end of the first suction part, to another end of the first suction part opposite to the one end, by forming internal pressure lower than external pressure, a transfer part including a first opening part, connected to the other end of the first suction part, through which the cover plastic film is introduced from the other end, and a second opening part through which the cover plastic film introduced through the first opening part flows out, a first nozzle disposed inside the transfer part and ejecting air in a first direction facing the second opening part, a discharge part connected to the second opening part in the first direction and discharging the cover plastic film transferred through the transfer part, and a plurality of guides forming a vortex inside the discharge part by being disposed inside the discharge part to have an inclination with respect to the first direction.

When recovering a plurality of cover plastic films, a plastic film recovery device according to an embodiment can reduce tangling of the cover plastic films during a process of transferring, by transferring using vortex. According to an embodiment, the plastic film recovery device can smoothly discharge the cover plastic film, by reducing the tangling of the cover plastic film.

According to an embodiment, the plastic film recovery device can simultaneously recover the cover plastic film discharged from a plurality of mounters, thereby simplifying the entire facility.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a state in which a plastic film recovery device is disposed, according to an embodiment of the disclosure;

FIG. 2 is a schematic cross-sectional view of a plastic film recovery device, according to an embodiment of the disclosure;

FIG. 3 is a schematic cross-sectional view of a discharge part of a plastic film recovery device, according to an embodiment of the disclosure;

FIG. 4A is an exploded view of a plastic film recovery device, according to an embodiment of the disclosure;

FIG. 4B is a perspective view of a state in which the plastic film recovery device illustrated in FIG. 4A is coupled according to an embodiment of the disclosure;

FIG. 5A is a perspective view of a first body of a discharge part of a plastic film recovery device, according to an embodiment of the disclosure;

FIG. 5B is a perspective view of FIG. 5A according to an embodiment of the disclosure;

FIG. 5C is a diagram viewed from direction B in FIG. 5B according to an embodiment of the disclosure;

FIG. 6 is a partial cross-sectional view illustrating a suction part and a transfer part of a plastic film recovery device, according to an embodiment of the disclosure;

FIG. 7 is a perspective view of a cover and a first nozzle of a plastic film recovery device, according to an embodiment of the disclosure;

FIG. 8 illustrates an example of an operation of a plastic film recovery device, according to an embodiment of the disclosure;

FIG. 9 is a cross-sectional view of a discharge part of a plastic film recovery device, according to an embodiment of the disclosure; and

FIG. 10 illustrates a plurality of guides of a plastic film recovery device, according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an integrated circuit (IC), or the like.

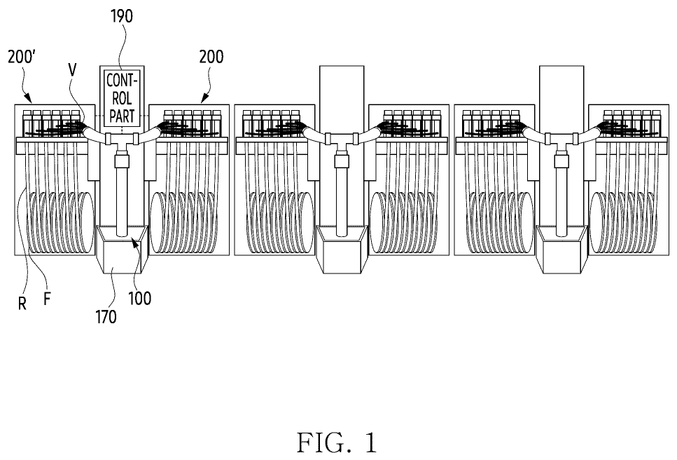

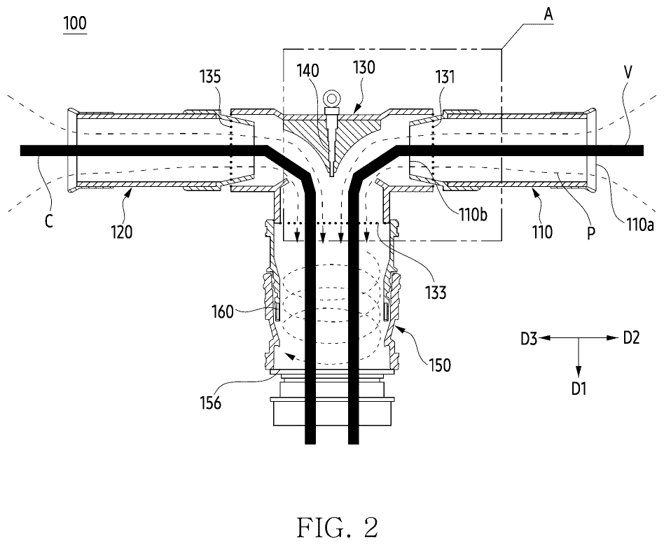

FIG. 1 illustrates a state in which a plastic film recovery device is disposed, according to an embodiment of the disclosure. FIG. 2 is a schematic cross-sectional view of a plastic film recovery device, according to an embodiment of the disclosure.

Referring to FIGS. 1 and 2, a plastic film recovery device 100 for recovery a cover plastic film V of reel tape R supplied to a mounter 200 may include a first suction part 110 transferring the cover plastic film V, which has been separated from the reel tape R and introduced into one end 110a of the first suction part 110, to another end 110b of the first suction part 110 opposite to the one end 110a, by forming internal pressure lower than external pressure; a transfer part 130 including a first opening part 131, connected to the other end 110b of the first suction part 110, through which the cover plastic film V is introduced from the other end 110b, and a second opening part 133 through which the cover plastic film V introduced through the first opening part 131 flows out; a first nozzle 140 disposed inside the transfer part 150 and ejecting (or discharging) air in a first direction D1 facing the second opening part 133; a discharge part 150 connected to the second opening part 133 in the first direction D1 and discharging the cover plastic film V transferred through the transfer part 130; and a plurality of holes 160, ejecting air for forming a vortex inside the discharge part 150 by being disposed inside the discharge part 150 to have an inclination with respect to the first direction D1.

A surface mount technology (SMT) is a technology that mounts a surface mounted components (SMC) on a surface of a printed circuit board. The SMT may be implemented by a mounter 200 that mounts components on the surface of the printed circuit board and soldering, and a feeder F that supplies the SMC in a form of reel tape R to the mounter 200. The feeder F may include a reel on which the reel tape R is wound. The reel tape R may include a base (e.g., paper) on which the SMC are placed and the cover plastic film V attached to the base to protect the SMC. The feeder F may transfer the reel tape R wound on the reel to the mounter 200. When the reel tape R is transferred to the mounter 200, the SMC may be supplied to the mounter 200 as the cover plastic film V of the reel tape R is taken off, and the cover plastic film V taken off may be discharged to the outside of the mounter 200. The plastic film recovery device 100 may recover the cover plastic film V discharged from the mounter 200.

According to an embodiment, the first suction part 110 may suction the cover plastic film V separated from the reel tape R, by forming an internal pressure lower than an external pressure. As the internal pressure of the first suction part 110 is lower than the external pressure, a negative pressure or vacuum may be formed inside the first suction part 110. By the negative pressure or vacuum, an airflow path P may be formed from one end 110a of the first suction part 110, to another end 110b opposite to the one end 110a.

According to an embodiment, the first suction part 110 may be located at a point where the cover plastic film V is discharged from the mounter 200. As the internal pressure of the first suction part 110 is formed lower than the external pressure, the first suction part 110 may suction the cover plastic film V separated from the reel tape R into the inside through the one end 110a. The cover plastic film V introduced through the one end 110a of the first suction part 110 may be transferred to the other end 110b of the first suction part 110, by the airflow path P formed inside the first suction part 110.

According to an embodiment, the cover plastic film V may be transferred from the one end 110a of the first suction part 110 to the other end 110b and then introduced into the transfer part 130. According to an embodiment, the transfer part 130 may include a first opening part 131 and a second opening part 133. The first opening part 131 may be connected to the other end 110b of the first suction part 110. The cover plastic film V introduced into the one end 110a of the first suction part 110 may be transferred along the inside of the first suction part 110 to the other end 110b of the first suction part 110, and then introduced into the inside of the transfer part 130 through the first opening part 131. The cover plastic film V introduced into the inside of the transfer part 130 through the first opening part 131 may be discharged to an outlet 156 through the second opening part 133.

According to an embodiment, the first nozzle 140 may eject (or discharge) air toward the second opening part 133, inside the transfer part 130. For example, inside the transfer part 130, the first nozzle 140 may eject air in the first direction D1 facing the second opening part 133. The first nozzle 140 may be connected to a compressed air supply device (not shown) supplying compressed air. The compressed air supplied from the compressed air supply device may be ejected in the first direction D1 through the first nozzle 140. For example, the first nozzle 140 may include a plurality of nozzles extending in the first direction D1. The first nozzle 140 may transfer the cover plastic film V introduced into the transfer part 130 through the first opening part 131 to the outside of the transfer part 130 through the second opening part 133, by ejecting the compressed air toward the first direction D1.

According to an embodiment, the discharge part 150 may provide a path through which the cover plastic film V transferred through the second opening part 133 of the transfer part 130 is discharged. According to an embodiment, the discharge part 150 may be connected to the second opening part 133 in the first direction D1, and may extend along the first direction D1. The discharge part 150 may include an outlet 156 for discharging the cover plastic film V at an end in the first direction D1. As the compressed air ejected from the first nozzle 140 transfers the cover plastic film V along the first direction D1 of the discharge part 150, the cover plastic film V may be discharged to the outside of the discharge part 150. Since the compressed air ejected from the first nozzle 140 forms the airflow path P in the first direction D1 inside the discharge part 150, the cover plastic film V may be transferred.

When the cover plastic film V is discharged from the transfer part 130 through the discharge part 150, as the extended cover plastic film V itself get tangled, it may not be discharged from the discharge part 150 and may be accumulated inside the discharge part 150. According to a comparative example, when the plastic film recovery device recovers the cover plastic film V supplied to a plurality of mounters, the cover plastic films V introduced from different directions become tangled with each other, and may be accumulated inside the discharge part. When the cover plastic film V is accumulated inside the discharge part, as the cover plastic film V may be not discharged smoothly, malfunction and/or failure of the plastic film recovery device may occur. According to an embodiment, the plastic film recovery device 100 may include a plurality of holes 160 capable of forming a vortex inside the discharge part 150, in order to smoothly discharge the cover plastic film V from the discharge part 150.

According to an embodiment, the plurality of holes 160 may be disposed inside the discharge part 150 and form a vortex inside the discharge part 150. The plurality of holes 160 may function as a path of compressed air. The plurality of holes 160 may form the vortex inside the discharge part 150, by being disposed inside the discharge part 150 to have an inclination with respect to the first direction D1. The discharge part may be connected to the compressed air supply device that supplies compressed air. The compressed air supplied from the compressed air supply device may be ejected the inside of the discharge part 150, through the plurality of holes 160 facing the inside of the discharge part 150. Since the plurality of holes 160 are disposed inside the discharge part 150 to have an inclination with respect to the first direction D1, when compressed air is ejected through the plurality of holes 160, the vortex may be formed. The compressed air ejected through the plurality of holes 160 may be not ejected linearly toward the first direction D1 in which the discharge part 150 extends, but be ejected to form the vortex, thereby reducing tangle of the cover plastic film V and reducing of accumulating the cover plastic film V inside the discharge part 150.

According to an embodiment, an accommodating part 170 for accommodating the cover plastic film V may be disposed at a position where the cover plastic film V is discharged from the discharge part 150. The accommodating part 170 may be connected to the first direction D1 of the discharge part 150 and may accommodate the cover plastic film V discharged from the discharge part 150. The cover plastic film V discharged from the discharge part 150 may be loaded in the accommodating part 170.

According to an embodiment, the plastic film recovery device 100 may recover the cover plastic film V discharged from the plurality of mounters 200. For example, according to an embodiment, the plastic film recovery device 100 may be disposed between two mounters 200 and recover the cover plastic film V discharged from the two mounters 200. According to an embodiment, the plastic film recovery device 100 may further include a second suction part 120 that introduces the cover plastic film V of the reel tape R, supplied to a mount 200′ disposed on one side, and the first suction part 110 may introduce the cover plastic film V of the reel tape R supplied to the mounter 200 disposed on another side. The second suction part 120 may substantially correspond the first suction part 110. For example, the cover plastic film V of the reel tape R supplied to the mount 200′ disposed on the one side of the plastic film recovery device 100 may be transferred to the transfer part 130 through the second suction part 120, and the cover plastic film V of the reel tape R supplied to the mounter 200 disposed on the other side of the plastic film recovery device 100 may be transferred to the transfer part 130 through the first suction part 110.

According to an embodiment, the first suction part 110 and the second suction part 120 may be connected to the transfer part 130, respectively. According to an embodiment, the transfer part 130 may further include a third opening part 135 connected to the second suction part 120. The first opening part 131 may be connected to the first suction part 110. The cover plastic film V introduced through the first suction part 110 and the second suction part 120 may be transferred to the discharge part 150 through the transfer part 130. The transfer part 130 may communicate the first suction part 110 and the second suction part 120 with the discharge part 150, by being connected to each of the first suction part 110 and the second suction part 120 and connected to the discharge part 150.

According to an embodiment, a plurality of mounters 200 may be disposed side by side along one direction, and one plastic film recovery device 100 may be disposed between the two mounters 200. The first suction part 110 and the second suction part 120 may face each other in opposite directions to be disposed at a position on which the cover plastic film V is discharged from two neighboring mounters 200, respectively. For example, the first suction part 110 may face a second direction D2 perpendicular to the first direction D1, and the second suction part 120 may face a third direction D3 opposite to the second direction D2.

According to an embodiment, the transfer part 130 may include the first opening part 131 connected to the first suction part 110 and the third opening part 135 connected to the second suction part 120, and the first opening part 131 and the third opening part 135 may face opposite directions. For example, the first opening part 131 may face the second direction D2, and the third opening part 135 may face the third direction D3. The cover plastic film V introduced into the inside of the transfer part 130 through the first opening part 131 and the third opening part 135 may be transferred to the discharge part 150 through the second opening part 133, by compressed air ejected from the first nozzle 140. According to an embodiment, the second opening part 133 may be disposed between the first opening part 131 and the third opening part 135. For example, the transfer part 130 may be generally a T-shape by the first opening part 131, the second opening part 133, and the third opening part 135 facing different directions, but is not limited thereto. The first nozzle 140 may be disposed toward the second opening part 133. For example, the first nozzle 140 may be disposed between the third opening part 135 and a fourth opening part.

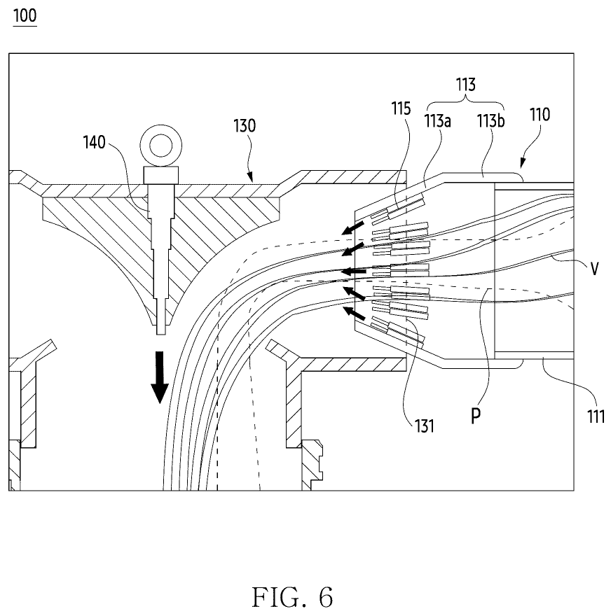

According to an embodiment, since the plastic film recovery device 100 may recover the cover plastic film V of the reel tape R supplied to the plurality of mounters 200, facilities for operating the entire system may be simplified. For example, when using a plastic film recovery device 100 available with respect to one mounter 200, it may be necessary to have the plastic film recovery device 100 for each mounter 200 to operate the entire system including the plurality of mounters 200. Since the plastic film recovery device 100 according to an embodiment may be used with respect to the plurality of mounters 200 (e.g., using one plastic film recovery device 100 for each of two mounters 200), facilities of the entire system may be simplified. Although FIG. 1 illustrates that one plastic film recovery device 100 is disposed between two mounters 200, it is not limited thereto. For example, the plastic film recovery device 100 according to an embodiment may be configured to be available with respect to three or more mounters 200 through two or more suction parts and transfer pipe 111 (e.g., transfer pipe 111 of FIG. 6) connected to the two or more suction parts.

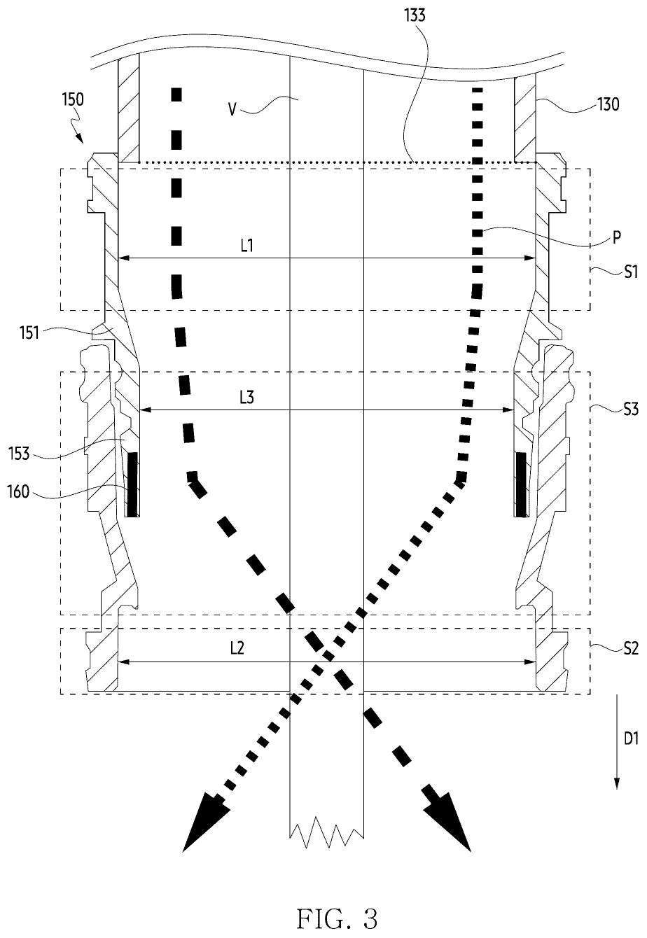

FIG. 3 is a schematic cross-sectional view of a discharge part of a plastic film recovery device, according to an embodiment of the disclosure.

Referring to FIG. 3, according to an embodiment, a discharge part 150 may extend along a first direction D1. The discharge part 150 may have different cross-sectional areas at different points (e.g., a first point S1, a second point S2, and a third point S3) distinguished with respect to the first direction D1. When compressed air ejected from a first nozzle (e.g., the first nozzle 140 of FIG. 2) flows along the first direction D1 of the discharge part 150, a flow rate may change according to Bernoulli principle while passing through the different cross-sectional area of the discharge part 150.

According to an embodiment, a cross-sectional area of the discharge part 150 connected to the second opening part 133 of the transfer part 130 at the first point S1 may be greater than a cross-sectional area of the discharge part 150 at the third point S3, between the first point S1 and the second point S2 where the cover plastic film V is discharged. For example, a diameter L1 of the discharge part 150 at the first point S1 may be about 50 mm, and a diameter L3 of the discharge part 150 at the third point S3 may be about 45 mm, but is not limited thereto.

According to an embodiment, when the compressed air ejected from the first nozzle 140 passes through the first point S1 and then passes through the second point S2, since the cross-sectional area of the second point S2 is smaller than the cross-sectional area of the first point S1, the pressure may be reduced and the flow rate may be increased according to Bernoulli principle. The cover plastic film V transferred along an airflow path P formed by the compressed air may be transferred at a relatively high speed when passing through the first point S1 and then the second point S2. When the cover plastic film V is transferred along the first direction D1 of the discharge part 150, a transfer speed at the second point S2 spaced apart in the first direction D1 with respect to the first point S1 may be greater than a transfer speed at the first point S1. According to an embodiment, the plastic film recovery device 100 may reduce a self-tangle of the cover plastic film V or a tangle of different cover plastic films V, by passing the cover plastic film V with a high speed at the second point S2.

According to an embodiment, the cross-sectional area of the discharge part 150 at the second point S2 may be greater than a cross-sectional area of the discharge part 150 at the third point S3. Since the second point S2 is a point where the cover plastic film V passing through the third point S3 is discharged to the outside of the discharge part 150, the cross-sectional area of the discharge part 150 at the second point S2 may be required to secure a sufficient cross-sectional area so that the cover plastic film V may be discharged smoothly. According to an embodiment, as the cross-sectional area of the discharge part 150 at the second point S2, which is a point where the cover plastic film V is discharged, is formed larger than the cross-sectional area of the discharge part 150 at the third point S3, the tangle of the cover plastic film V is prevented, and the cover plastic film V may be discharged smoothly.

According to an embodiment, the cross-sectional area of the discharge part 150 at the second point S2 may correspond to the cross-sectional area of the discharge part 150 at the first point S1. For example, the diameter L1 of the discharge part 150 at the first point S1 is about 50 mm, the diameter L3 of the discharge part 150 at the third point S3 is about 45 mm, and a diameter L2 of the discharge part 150 at the second point S2 may be about 50 mm, but is not limited thereto.

According to an embodiment, the plurality of holes 160 may be disposed at the third point S3. The plurality of holes 160 may be disposed at the third point S3 inside a first body 151 to form a vortex inside the discharge part 150. When the plurality of holes 160 are disposed at the first point S1, since the vortex is formed throughout the discharge part 150, different cover plastic films V may get tangled, and when the plurality of holes 160 are disposed at the second point S2, since the vortex is formed at a point where the cover plastic film V is discharged, the effect of the vortex may be very small. According to an embodiment, the plurality of holes 160 may be disposed at the third point S3 so that the vortex may be formed at the third point S3 for a smooth transfer of the cover plastic film V.

According to an embodiment, compressed air ejected from the first nozzle 140 toward the first direction D1 may pass through the second opening part 133 and be introduced into the inside of the discharge part 150. When passing through the first point S1, the third point S3, and the second point S2 of the discharge part 150 in sequence, the compressed air ejected from the first nozzle 140 may change a flow rate and pressure while passing through different cross-sectional areas. Based on a change in the flow rate of the compressed air ejected from the first nozzle 140, a transfer speed of the cover plastic film V may change. As described above, a cross-sectional area at the third point S3 may be smaller than a cross-sectional area at the first point S1 for reducing the tangle of the cover plastic film V within the discharge part 150, and a cross-sectional area at the second point S2 may be greater than the cross-sectional area at the third point S3 for smooth discharge of the cover plastic film V from the discharge part 150. According to an embodiment, as the discharge part 150 has different cross-sectional areas along the first direction D1, the cover plastic film V may be transferred with a relatively small force, and the cover plastic film V may be smoothly discharged without getting tangled.

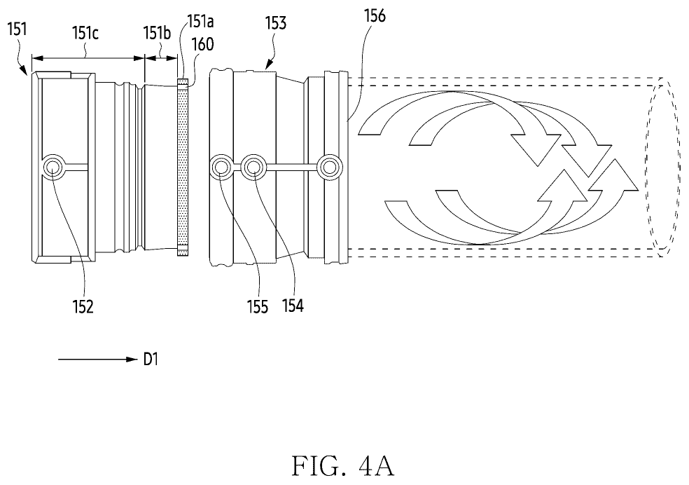

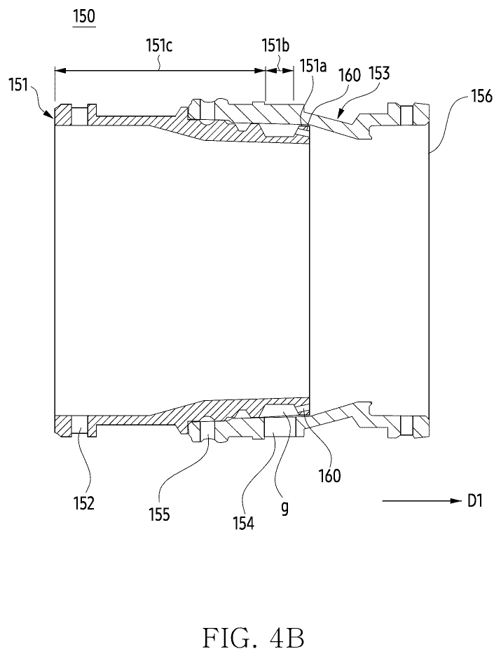

FIG. 4A is an exploded view of a plastic film recovery device, according to an embodiment of the disclosure. FIG. 4B is a perspective view of a state in which the plastic film recovery device illustrated in FIG. 4A is coupled according to an embodiment of the disclosure.

Referring to FIGS. 4A and 4B, a discharge part 150 may include a first body 151 and a second body 153. According to an embodiment, the discharge part 150 may include the first body 151 connected to a second opening part (e.g., the second opening part 133 of FIG. 2) of a transfer part (e.g., the transfer part 130 of FIG. 2) and including a plurality of holes 160, and the second body 153 connected to the first body 151 in a first direction D1 and including an outlet 156 through which the cover plastic film V transferred from the first body 151 is discharged to the outside of the discharge part 150.

According to an embodiment, the first body 151 and the second body 153 may be connected to each other along the first direction D1. The first body 151 may include a first fixing part 152 connected to the second opening part 133 of the transfer part 130. The first body 151 may be positioned in the first direction D1 with respect to the second opening part 133 of the transfer part 130, and may be fixed to the second opening part 133 through the first fixing part 152. For example, at least a part of the second opening part 133 may be inserted into the first body 151, and the first fixing part 152 may be disposed at a point in contact with the second opening part 133 of the first body 151. In a state in which at least a part of the second opening part 133 is inserted into the first body 151, the first body 151 may be fixed to the second opening part 133 by the first fixing part 152.

According to an embodiment, at least a part of the first body 151 may be inserted into the inside of the second body 153 along the first direction D1. In a state in which a part of the first body 151 is inserted into the inside of the second body 153, the second body 153 and the first body 151 may be coupled to each other. For example, in a state in which a part of the first body 151 is inserted into the inside of the second body 153, the first body 151 and the second body 153 may be coupled to each other through a second fixing part 155 of the second body 153.

According to an embodiment, the second body 153 may include a compressed air inlet 154 through which compressed air is supplied. For example, a compressed air supply device (not illustrated) supplying compressed air and the compressed air inlet 154 of the second body 153 may be connected to each other. In a state of being inserted into the second body 153, the first body 151 may include a first area 151b, which is an area corresponding to the compressed air inlet 154, a flange 151a including the plurality of holes 160, and a second area 151c distinguished from the first area 151b. The flange 151a may be disposed at an end portion of the first body 151 in the first direction D1. The compressed air introduced through the compressed air inlet 154 may be introduced into a gap g between the first area 151b of the first body 151 and the second body 153. The compressed air introduced into the gap g may be ejected to the inside of the discharge part 150, by passing through the plurality of holes 160 formed in the flange 151a. When the compressed air is ejected to the inside of the discharge part 150 through the plurality of holes 160, a vortex may be formed by an inclination of the plurality of holes 160. Although not illustrated, a packing member (e.g., an O-ring) for sealing the first area 151b may be provided on an outer circumference surface of the second area 151c. The first area 151b may be sealed by the packing member and the flange 151a. The compressed air introduced into the gap g through the compressed air inlet 154 may stay in the gap by the packing member and the flange 151a.

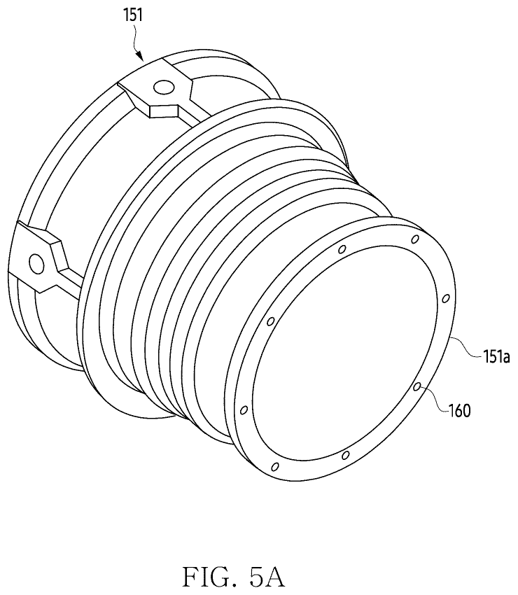

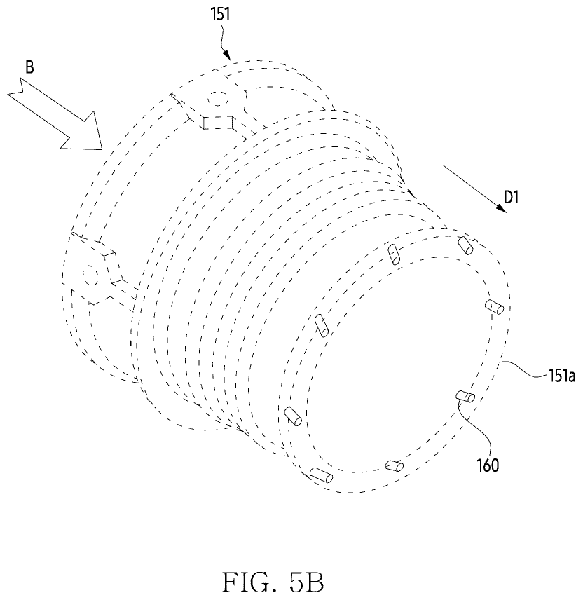

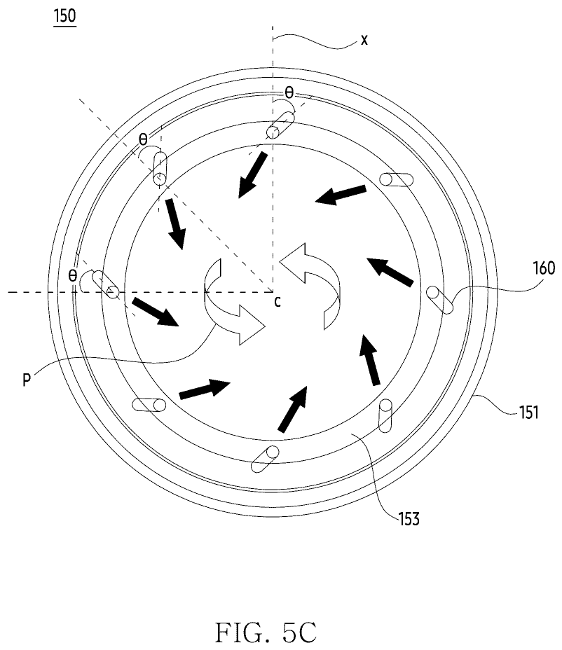

FIG. 5A is a perspective view of a first body of a discharge part of a plastic film recovery device, according to an embodiment of the disclosure. FIG. 5B is a perspective view of FIG. 5A according to an embodiment of the disclosure, and FIG. 5C is a diagram viewed from direction B in FIG. 5B according to an embodiment of the disclosure.

Referring to FIG. 5A, a plurality of holes 160 may be disposed at regular intervals along a circumferential direction of a flange 151a disposed at an end of a first body 151. For example, the first body 151 may include eight holes 160 spaced at regular intervals in the circumferential direction of the flange 151a, and the eight holes 160 may be formed by passing through the flange 151a. The compressed air introduced through a compressed air inlet 154 may be ejected to the inside of a discharge part (e.g., the discharge part 150 of FIG. 2), by passing through the plurality of holes 160.

Referring to FIG. 5B, the plurality of holes 160 may extend with an inclination with respect to a first direction D1 inside the flange 151a. When the compressed air is ejected to the inside of the discharge part 150 through the plurality of holes 160, the compressed air may be ejected in a direction in which the plurality of holes 160 extend. When the first body 151 illustrated in FIG. 5B is viewed from direction B, the plurality of holes 160 may each extend in different directions, and air ejected to the inside of the discharge part 150 through the plurality of holes 160 may form a vortex inside the discharge part 150.

Referring to FIG. 5C, the plurality of holes 160 may have an inclination with respect to a generatrix X of the discharge part 150. The generatrix X may mean a virtual straight line forming an inner surface of the discharge part 150. For example, the generatrix X may be a virtual straight line extending perpendicular to the circumferences forming the inner surface of the discharge part 150. According to an embodiment, since a cross-sectional area of the first body 151 may have different cross-sectional areas at different points distinguished with respect to the first direction D1, the generatrix X of the discharge part 150 may extend toward the same center C. For example, a cross-sectional area at a point connected to the second opening part (e.g., the second opening part 133 of FIG. 2) of the first body 151 may be greater than a cross-sectional area of the flange 151a disposed at an end of the first body 151. According to an embodiment, the generatrix X of the discharge part 150 at each positions of the plurality of holes 160 may extend toward the same center C.

According to an embodiment, the plurality of holes 160 may have an inclination angle θ with respect to the generatrix X of the discharge part 150. The plurality of holes 160 may have the same inclination angle θ with respect to the generatrix X of the discharge part 150 at each positions. When the inclination angle θ is too small, it may be difficult to form a vortex substantially, and when the inclination angle θ is too large, it may be difficult to form an airflow path P that transfers the cover plastic film V in the first direction D1. The inclination angle θ may be an angle capable of forming a vortex capable of smoothly transferring the cover plastic film V, inside the discharge part 150. For example, the inclination angle θ may be about 5 degrees to 20 degrees, but is not limited thereto.

According to an embodiment, since the compressed air ejected from the plurality of holes 160 is ejected so as to cross each other toward a center C of the discharge part 150, a vortex generally facing the first direction D1 may be formed inside the discharge part 150. Since the cover plastic film V is transferred along the airflow path P inside the discharge part 150, the cover plastic film V may be smoothly discharged without getting tangled, by the vortex formed inside the discharge part 150.

FIG. 6 is a partial cross-sectional view illustrating a suction part and a transfer part of a plastic film recovery device, according to an embodiment of the disclosure. FIG. 6 corresponds a diagram where a part A of FIG. 2 is enlarged.

Referring to FIG. 6, a first suction part 110 may include a transfer pipe 111 through which a cover plastic film V is introduced and to which the introduced cover plastic film V is transferred, and a connecting member 113, disposed between the transfer pipe 111 and the first opening part 131, connecting the transfer pipe 111 and the first opening part 131 and including a plurality of second nozzles 115 ejecting air toward the first opening part 131.

According to an embodiment, the cover plastic film V separated from reel tape R may be transferred through the transfer pipe 111. One end of the transfer pipe 111 (e.g., the one end 110a of FIG. 2) may be positioned at a position where the cover plastic film V is discharged, and another end 110b of the transfer pipe 111 may be connected to the first opening part 131 of the transfer part 130. According to an embodiment, the plastic film recovery device 100 may freely adjust a position and a shape of the transfer pipe 111 so that the cover plastic film V discharged from a plurality of mounters 200 is recovered. According to an embodiment, the transfer pipe 111 may include a flexible material.

According to an embodiment, the connecting member 113 may be disposed between the transfer pipe 111 and the first opening part 131 to connect the transfer pipe 111 and the first opening part 131. The transfer pipe 111 may be connected to the transfer part 130 through the connecting member 113. By packing between the transfer pipe 111 and the transfer part 130, the connecting member 113 may prevent leakage of compressed air.

According to an embodiment, the plurality of second nozzles 115 may be disposed at the connecting member 113 and eject compressed air from the transfer pipe 111 toward the first opening part 131. By the compressed air ejected from the plurality of second nozzles 115, an airflow path from one end (e.g., the one end 110a of FIG. 2) of the first suction part 110 toward another end (e.g., the other end 110b of FIG. 2) may be formed. The plurality of second nozzles 115 may transfer the cover plastic film V to the transfer part 130, by forming a negative pressure or vacuum of the transfer pipe 111.

According to an embodiment, the connecting member 113 may include an area 113b coupled to the transfer pipe 111 and a narrow area 113a with reduced cross-sectional area. The plurality of second nozzles 115 may be disposed inside the narrow area 113a and may be spaced apart from each other, in order to face the center of the connecting member 113. For example, the narrow area 113a may have a shape where a cross-sectional area is gradually reduced in a direction in which the cover plastic film V is transferred. The plurality of second nozzles 115 may face a center of the connecting member 113, by being disposed in the narrow area 113a. Since the plurality of second nozzles 115 face the center of the connecting member 113, compressed air ejected from the plurality of second nozzles 115 may be ejected to a center of the connecting member 113. As the plurality of second nozzles 115 ejects out the compressed air toward the center of the connecting member 113, an airflow path P toward the center of the connecting member 113 may be formed inside the transfer pipe 111. According to an embodiment, when the cover plastic film V is transferred from inside the transfer pipe 111, it may be moved to the center of the connecting member 113 by the airflow path P toward the center of the connecting member 113. Since the cover plastic film V moves toward the center of the connecting member 113, it may be transferred from inside of the transfer pipe 111 toward the center in a state of being floated.

When the compressed air ejected from the plurality of second nozzles 115 is ejected in a straight line toward the first opening part 131, the cover plastic film V may be transferred in a state of being in contact with an inner surface of the transfer pipe 111. When the cover plastic film V is transferred in a state of being in contact with the inner surface of the transfer pipe 111, the cover plastic film V may not be transferred smoothly due to friction between the cover plastic film V and the inner surface.

According to an embodiment, since the plurality of second nozzles 115 are disposed in the narrow area 113a of the connecting member 113, when being transferred from inside the transfer pipe 111, the cover plastic film V may be transferred in a state of being floated toward the center from inside the transfer pipe 111 without being in contact with an inner circumference surface of the transfer pipe 111. According to an embodiment, the cover plastic film V may be transferred smoothly, by minimizing a contact between the cover plastic film V and the inner surface of the transfer pipe 111.

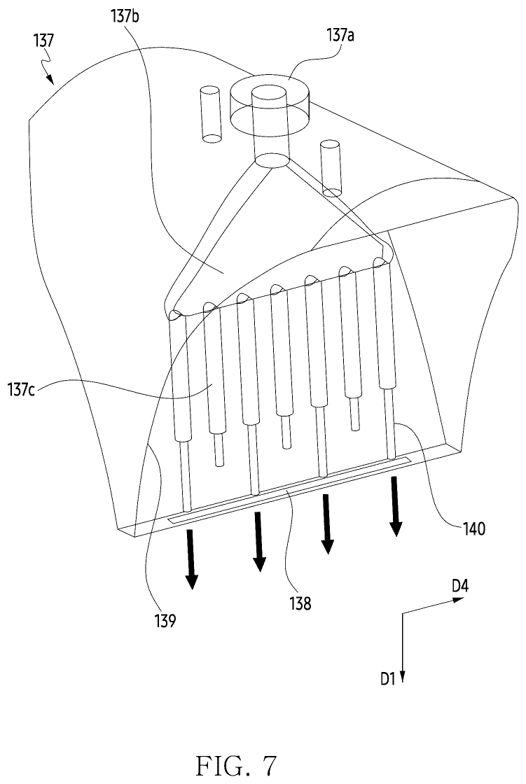

FIG. 7 is a perspective view of a cover and a first nozzle of a plastic film recovery device, according to an embodiment of the disclosure.

Referring to FIG. 7, a transfer part 130 may include a cover 137 accommodating a first nozzle 140, and the cover 137 may comprise an opening part 138 discharging compressed air by connecting the first nozzle 140, and an outer wall 139 separating an inner space of the transfer part (e.g., the transfer part 130 of FIG. 2) and a space where the first nozzle 140 is disposed.

According to an embodiment, the cover 137 may accommodate the first nozzle 140 therein. When compressed air is ejected from the first nozzle 140, noise due to a compressed airflow path P may occur. The cover 137 may reduce noise generated from the compressed air ejected from the first nozzle 140, by surrounding the first nozzle 140 ejected the compressed air.

According to an embodiment, the cover 137 may include a compressed air inlet 137a through which compressed air is introduced and an inner space 137b between the compressed air inlet 137a and the first nozzle 140. The compressed air may be supplied from a compressed air supply device (not shown) through the compressed air inlet 137a. The compressed air may be introduced into the inner space 137b through the compressed air inlet 137a. The compressed air may be supplied to the first nozzle 140 while expanding through the inner space 137b, and may be ejected into the transfer part 130 in a first direction D1. Since the compressed air may partially expand in the inner space 137b, noise may be reduced when being ejected through the first nozzle 140.

According to an embodiment, the first nozzle 140 may include a plurality of nozzles spaced apart from each other. The plurality of nozzles may be disposed along a fourth direction D4 perpendicular to the first direction D1. A groove 137c connected with the inner space 137b may be formed between the plurality of nozzles. Since the compressed air may flow into the groove 137c, the groove 137c may provide a space in which the compressed air may expand. According to an embodiment, noise may be reduced by mitigating rapid expansion of the compressed air by the groove 137c.

According to an embodiment, the compressed air ejected from the first nozzle 140 may be ejected to the inside of the transfer part 130 through the opening part 138 of the cover 137. The opening part 138 may be formed along the fourth direction. For example, the opening part 138 may be adjacent to a part where the compressed air is ejected from the first nozzle 140 and may extend in the fourth direction.

According to an embodiment, an outer wall 139 may have a shape rounded toward a second opening part (e.g., the second opening part 133 of FIG. 2) from a first opening part (e.g., the first opening part 131 of FIG. 2). For example, when the first opening part 131 and the second opening part 133 are perpendicular to each other, the outer wall 139 may have approximately a shape of a quadrant arc. When the transfer part 130 includes the first opening part 131 and the third opening part 135, the outer wall 139 may include a part rounded from the first opening part 131 toward the second opening part 133 and a part rounded from the third opening part 135 toward the second opening part 133. According to an embodiment, since the outer wall 139 has a rounded shape, a noise reduction effect may be improved.

When the first nozzle 140 is directly exposed to the inside of the transfer pipe 111 without the cover 137, noise may occur due to the rapid expansion of the compressed air when the compressed air is ejected to the inside of the transfer pipe 111. According to an embodiment, the cover 137 may reduce noise by surrounding the first nozzle 140. According to an embodiment, since the compressed air partially expands in the inner space 137b of the cover 137 before being ejected through the first nozzle 140, noise may be reduced.

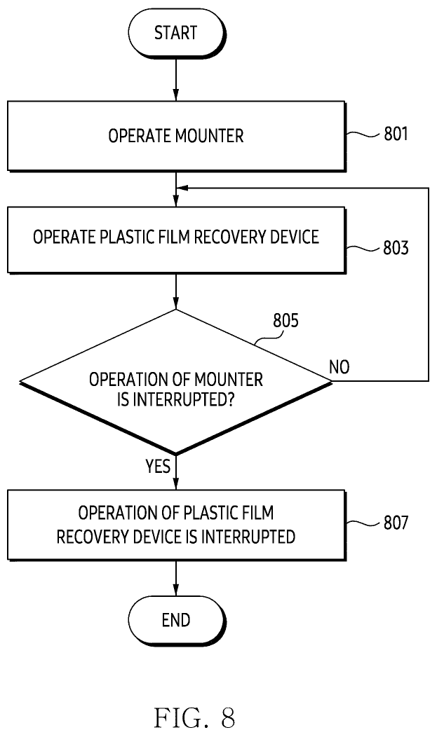

FIG. 8 illustrates an example of an operation of a plastic film recovery device, according to an embodiment of the disclosure

Referring to FIG. 8, according to an embodiment, a plastic film recovery device (e.g., plastic film recovery device 100 of FIG. 2) may further comprise a control part (e.g., control part 190 of FIG. 1) operatively connected to a mounter (e.g., mounter 200 of FIG. 1), and the control part 190 may be configured to operate the plastic film recovery device 101 in response to identifying operation of the mounter 200, and interrupt the operation of the plastic film recovery device 100, in response to identifying an interruption in operation of the mounter 200.

In operation 801, the operation of the mounter 200 may be initiated. When the operation of the mounter 200 is initiated, a feeder (e.g., the feeder F of FIG. 1) may supply reel tape (e.g., the reel tape R of FIG. 1) to the mounter 200, and a cover plastic film (e.g., the cover plastic film V of FIG. 1) separated from the reel tape R may be discharged.

In operation 803, in response to identifying the operation of the mounter 200, an operation of the plastic film recovery device 100 may be initiated. The control part 190 operatively connected to the mounter 200 may operate the plastic film recovery device 100, in response to identifying the operation of the mounter 200. According to an embodiment, the control part 190 may control the overall operation of the plastic film recovery device 100. For example, in order to form internal pressure of the plastic film recovery device 100 lower than external pressure, the control part 190 may operate an air supply device that supplies compressed air to a first nozzle (e.g., the first nozzle 140 of FIG. 1), a plurality of second nozzles (e.g., the plurality of second nozzles 115 of FIG. 6), and/or a plurality of holes (e.g., the plurality of holes 160 of FIG. 2).

In operation 805, the plastic film recovery device 100 may identify whether the operation of the mounter 200 is interrupted. When the operation of the mounter 200 is interrupted, in operation 807, the operation of the plastic film recovery device 100 may be interrupted. The control part 190 may interrupt the operation of the plastic film recovery device 100, in response to identifying an interruption of the operation of the mounter 200. When the mounter 200 is continuously operated, the plastic film recovery device 100 may be continuously operated.

According to an embodiment, the control part 190 may control the operation of the plastic film recovery device 100, based on the operation of the mounter 200. According to an embodiment, when the plastic film recovery device 100 is operated, the control part 190 may recover the cover plastic film V discharged from the mounter 200, by operating the plastic film recovery device 100. When the operation of the mounter 200 is initiated, the plastic film recovery device 100 may initiate operating to recover the cover plastic film V, even when the plastic film recovery device 100 is not operated separately. According to an embodiment, when the operation of the plastic film recovery device 100 is interrupted, the control part 190 may prevent the plastic film recovery device 100 from operating in a situation where recovery of the cover plastic film V is unnecessary, by interrupting the operation of the plastic film recovery device 100.

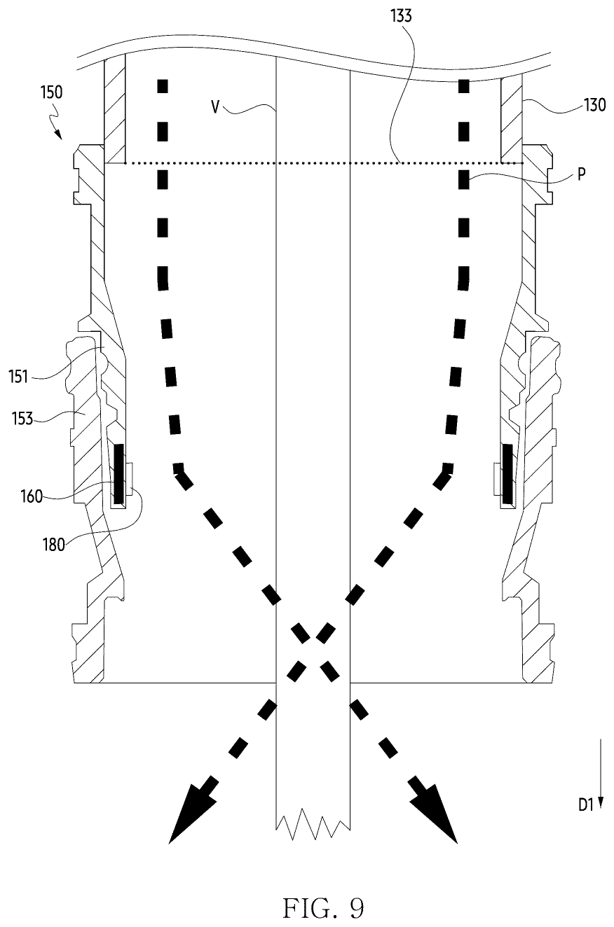

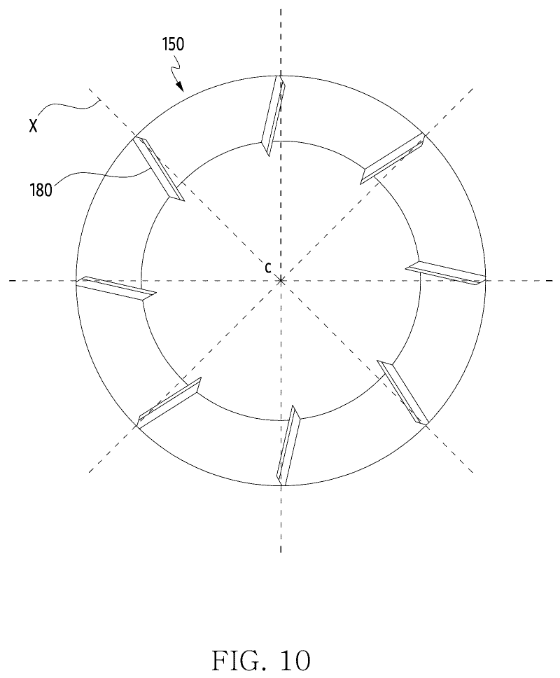

FIG. 9 is a cross-sectional view of a discharge part of a plastic film recovery device, according to an embodiment of the disclosure. FIG. 10 illustrates a plurality of guides of a plastic film recovery device, according to an embodiment of the disclosure.

Referring to FIGS. 9 and 10, according to an embodiment, a plastic film recovery device (e.g., plastic film recovery device 100 of FIG. 2) may include a plurality of guides 180 forming a vortex inside the discharge part 150, by being disposed inside the discharge part 150 to have an inclination based on a first direction D1.

According to an embodiment, the plurality of guides 180 may guide a flow of compressed air ejected from a first nozzle (e.g., the first nozzle 140 of FIG. 2), by being disposed on an inner surface of the discharge part 150. According to an embodiment, when the compressed air is ejected from the first nozzle 140 toward a first direction D1, the compressed air may be introduced into the inside of the discharge part 150, through a second opening part 133 of a transfer part 130. An airflow path P may be formed according to a flow of the compressed air, and a cover plastic film V may be transferred by the airflow path P. Since the compressed air is ejected from the first nozzle 140 toward the first direction D1, when the compressed air is introduced into the discharge part 150, an airflow path P facing the first direction D1 may be formed. According to an embodiment, when the compressed air passes through the inside of the discharge part 150, since the airflow path P is guided by the plurality of guides 180, a vortex may be formed inside the discharge part 150.

When the plurality of guides 180 are disposed too close with respect to the second opening part 133, since a vortex is formed before a transfer speed of the cover plastic film V increases, the cover plastic film V may get tangled. When the plurality of guides 180 are disposed too far with respect to the second opening part 133, an area in which a vortex is formed inside the discharge part 150 may be too narrow. According to an embodiment, the plurality of guides 180 may be disposed at a point where a flow rate of compressed air passing through the discharge part 150 increases. For example, the plurality of guides 180 may be disposed at an end part of a first body 151. For another example, the plurality of guides 180 may be disposed at a point (e.g., the third point S3 of FIG. 3) where a cross-sectional area of the discharge part 150 is reduced. According to an embodiment, since the plurality of guides 180 are disposed at a point where a cross-sectional area of the discharge part 150 is reduced, a vortex may be formed at a point where a transfer speed of the cover plastic film V increases.

According to an embodiment, the plurality of guides 180 may have an inclination with respect to a generatrix X of the discharge part 150, inside the discharge part 150. The generatrix X may mean a virtual line extending in the first direction D1 along an inner surface of the first body 151. The plurality of guides 180 may have the same inclination angle θ with respect to the generatrix X of the discharge part 150, at each position. The plurality of guides 180 may be disposed in a radial pattern as a whole.

According to an embodiment, the airflow path P facing the first direction D1 may be changed by the plurality of guides 180 having an inclination with respect to the generatrix X of the discharge part 150. The compressed air ejected from the first nozzle 140 may form a vortex toward a center C of the discharge part 150 while passing through the plurality of guides 180. Since a vortex is formed inside the discharge part 150 by the compressed air ejected from the first nozzle 140, tangle of the cover plastic film V may be reduced. According to an embodiment, the vortex formed by the plurality of guides 180 may smoothly transfer the cover plastic film V.

According to an embodiment, the plurality of guides 180 may be disposed adjacent to a point where the plurality of holes 160 are disposed in the discharge part 150. Referring to FIG. 9, the plurality of holes 160 may be disposed at an end of the first body 151 of the discharge part 150, and the plurality of guides 180 may be disposed adjacent to a point where the plurality of holes 160 are disposed in the discharge part 150. According to an embodiment, the plastic film recovery device 100 may easily form a vortex, by the plurality of holes 160 and the plurality of guides 180.

According to an embodiment, a plastic film recovery device (e.g., the plastic film recovery device 100 of FIG. 1) for recovering a cover plastic film (e.g., the cover plastic film V of FIG. 1) of reel tape (e.g., the reel tape R of FIG. 1) supplied to a mounter (e.g., the mounter 200 of FIG. 1) may comprise a first suction part (e.g., the first suction part 110 of FIG. 2), a transfer part (e.g., the transfer part 130 of FIG. 2), a first nozzle (e.g., the first nozzle 140 of FIG. 2), a discharge part (e.g., the discharge part 150 of FIG. 2), and a plurality of holes (e.g., the plurality of holes 160 of FIG. 2). According to an embodiment, the first suction part may transfer the cover plastic film, which has been separated from the reel tape and introduced into one end (e.g., the one end 110a of FIG. 2), to another end (e.g., the other end 110b of FIG. 2) opposite to the one end, by forming a negative pressure or vacuum inside. According to an embodiment, the transfer part may include a first opening part (e.g., the first opening part 131 of FIG. 2), coupled to the other end of the first suction part, through which the cover plastic film is introduced from the other end, and a second opening part (e.g., the second opening part 133 of FIG. 2) through which the cover plastic film introduced through the first opening part flows out. According to an embodiment, the first nozzle may eject air in a first direction (e.g., the first direction D1 of FIG. 2) facing the second opening part, inside the transfer part. According to an embodiment, the discharge part may be coupled to the second opening part in the first direction and discharge the cover plastic film transferred through the transfer part. According to an embodiment, the plurality of holes, by being positioned inside the discharge part to have an inclination with respect to the first direction, may form a vortex inside the discharge part.

According to an embodiment, the plurality of holes may have the inclination with respect to a generatrix (e.g., the generatrix X of FIG. 5C) of the discharge part.

According to an embodiment, the plastic film recovery device may further comprise an accommodating part (e.g., the accommodating part 170 of FIG. 1) coupled to the discharge part in the first direction and storing the cover plastic film discharged from the discharge part.

According to an embodiment, the first suction part may include a transfer pipe (e.g., the transfer pipe 111 of FIG. 6) and a plurality of second nozzles (e.g., the plurality of second nozzles 115 of FIG. 6). According to an embodiment, the transfer pipe through which the cover plastic film is introduced, and to which the introduced cover plastic film may be transferred. According to an embodiment, the connecting member may be positioned between the transfer pipe and the first opening part, connect the transfer pipe and the first opening part, and include a plurality of second nozzles (e.g., the plurality of second nozzles 115 of FIG. 6) ejecting air toward the first opening part.

According to an embodiment, the transfer pipe may be configured with a flexible material.

According to an embodiment, the connecting member may comprise a narrow area with reduced cross-sectional area. According to an embodiment, the plurality of second nozzles may be positioned inside the narrow area to face a center of the connecting member, and spaced apart from each other.

According to an embodiment, the transfer part may include a cover (e.g., the cover 137 of FIG. 7) accommodating the first nozzle. According to an embodiment, the cover comprise an opening part (e.g., the opening part 138 of FIG. 7) and an outer wall (e.g., the outer wall 139 of FIG. 7). According to an embodiment, the opening part may eject compressed air by coupling the first nozzle. According to an embodiment, the outer wall may separate an inner space of the transfer part and a space where the first nozzle is disposed.

According to an embodiment, the outer wall may have a rounded shape from the first opening part toward the second opening part.

According to an embodiment, the discharge part may include a first body (e.g., the first body 151 of FIG. 3) and a second body (e.g., the second body 153 of FIG. 3). According to an embodiment, the first body may be coupled to the second opening part of the transfer part and comprise the plurality of holes. According to an embodiment, the second body may be coupled to the first body in the first direction and comprise an outlet (e.g., the outlet 156 of FIG. 2) through which the cover plastic film transferred from the first body is discharged to the outside of the discharge part.

According to an embodiment, a first cross-sectional area of the discharge part connected to the second opening part at a first point (e.g., the first point S1 of FIG. 3) may be greater than a third cross-sectional area of the discharge part at a third point (e.g., the third point S3 of FIG. 3) between the first point and a second point (e.g., the second point S2 of FIG. 3) where the cover plastic film is discharged.

According to an embodiment, a second cross-sectional area of the discharge part at the second point may be greater than the third cross-sectional area at the third point of the discharge part.

According to an embodiment, the second cross-sectional area of the discharge part at the second point may correspond to the first cross-sectional area of the discharge part at the first point.

According to an embodiment, the cross-sectional area of the discharge part at the second point may be greater than the cross-sectional area of the discharge part at the third point.

According to an embodiment, the plurality of holes are positioned in the third point.

According to an embodiment, the plastic film recovery device may be positioned between two mounters. According to an embodiment, the plastic film recovery device further comprises a second suction part. According to an embodiment, the second suction part may introduce the cover plastic film of the reel tape supplied to a first mounter positioned on one side of the plastic film recovery device of the two mounters. According to an embodiment, the first suction part may introduce the cover plastic film of the reel tape supplied to a second mounter positioned on another side of the plastic film recovery device of the two mounters.

According to an embodiment, the transfer part may further comprise a third opening part (e.g., the third opening part 135 of FIG. 2) connected to the second suction part. According to an embodiment, the first opening part may be coupled to the first suction part.

According to an embodiment, the second opening part may be positioned between the first opening part and the second opening part.

According to an embodiment, the first nozzle may be positioned between the first opening part and the third opening part.

According to an embodiment, the plastic film recovery device may further comprise a control part (e.g., the control part 190 of FIG. 1) operatively connected to the mounter. According to an embodiment, the control part may be configured to operate the plastic film recovery device in response to identifying operation of the mounter. According to an embodiment, the control part may be configured to interrupt the operation of the plastic film recovery device, in response to identifying an interruption in operation of the mounter.

According to an embodiment, a plastic film recovery device (e.g., the plastic film recovery device 100 of FIG. 1) for recovering a cover plastic film (e.g., the cover plastic film V of FIG. 1) of reel tape (e.g., the reel tape R of FIG. 1) supplied to a mounter (e.g., the mounter 200 of FIG. 1) may comprise a first suction part (e.g., the first suction part 110 of FIG. 2), a transfer part (e.g., the transfer part 130 of FIG. 2), a first nozzle (e.g., the first nozzle 140 of FIG. 2), a discharge part (e.g., the discharge part 150 of FIG. 2), and a plurality of guides (e.g., the plurality of guides 180 of FIG. 9). According to an embodiment, the first suction part may transfer the cover plastic film, separated from the reel tape and introduced into one end (e.g., the one end 110a of FIG. 2), to another end (e.g., the other end 110b of FIG. 2) opposite to the one end, by forming a negative pressure or vacuum inside. According to an embodiment, the transfer part may include a first opening part (e.g., the first opening part 131 of FIG. 2), coupled to the other end of the first suction part, through which the cover plastic film is introduced from the other end, and a second opening part (e.g., the second opening part 133 of FIG. 2) through which the cover plastic film introduced through the first opening part flows out. According to an embodiment, the first nozzle may eject air in a first direction (e.g., the first direction D1 of FIG. 2) facing the second opening part, inside the transfer part. According to an embodiment, the discharge part may be connected to the second opening part in the first direction and discharge the cover plastic film transferred through the transfer part. According to an embodiment, the plurality of guides, by being positioned inside the discharge part to have an inclination with respect to the first direction, may form a vortex inside the discharge part.

According to an embodiment, the plurality of guides may have an inclination with respect to a generatrix (e.g., the generatrix X of FIG. 10) of the discharge part.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., program) including one or more instructions that are stored in a storage medium (e.g., internal memory or external memory) that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device individually or collectively, cause the electronic device to perform a method of the disclosure.

Any such software may be stored in the form of volatile or non-volatile storage such as, for example, a storage device like read only memory (ROM), whether erasable or rewritable or not, or in the form of memory such as, for example, random access memory (RAM), memory chips, device or integrated circuits or on an optically or magnetically readable medium such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

No claim element is to be construed under the provisions of 35 U.S.C. § 112, sixth paragraph, unless the element is expressly recited using the phrase “means for” or “means.”

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A plastic film recovery device for recovering a cover plastic film of reel tape supplied to a mounter, the plastic film recovery device comprising:
a first suction part transferring the cover plastic film, which has been separated from the reel tape and introducing into one end of the first suction part to another end of the first suction part opposite to the one end, by forming internal pressure lower than external pressure;
a transfer part including:
a first opening part, connected to the other end of the first suction part, through which the cover plastic film is introduced from the other end, and
a second opening part through which the cover plastic film introduced through the first opening part flows out;
a first nozzle disposed inside the transfer part and ejecting air in a first direction facing the second opening part;
a discharge part connected to the second opening part in the first direction and discharging the cover plastic film transferred through the transfer part; and
a plurality of holes ejecting air for forming a vortex inside the discharge part by being disposed inside the discharge part to have an inclination with respect to the first direction.

2. The plastic film recovery device of claim 1, wherein the plurality of holes have the inclination with respect to a generatrix of the discharge part.

3. The plastic film recovery device of claim 1, further comprising:
an accommodating part connected to the discharge part in the first direction and accommodating the cover plastic film discharged from the discharge part.

4. The plastic film recovery device of claim 1, wherein the first suction part comprises:
a transfer pipe through which the cover plastic film is introduced, and to which the introduced cover plastic film is transferred; and
a connecting member, disposed between the transfer pipe and the first opening part, connecting the transfer pipe and the first opening part and including a plurality of second nozzles ejecting air toward the first opening part.

5. The plastic film recovery device of claim 4,
wherein the transfer pipe comprises a flexible material.

6. The plastic film recovery device of claim 4,
wherein the connecting member comprises a narrow area with reduced cross-sectional area,
wherein the plurality of second nozzles are disposed inside the narrow area to face a center of the connecting member, and
wherein the plurality of second nozzles are spaced apart from each other.

7. The plastic film recovery device of claim 1,
wherein the transfer part includes a cover accommodating the first nozzle, and
wherein the cover comprises:
an opening part ejecting air by connecting the first nozzle; and
an outer wall separating an inner space of the transfer part and a space where the first nozzle is disposed.

8. The plastic film recovery device of claim 7,
wherein the outer wall has a shape rounded toward a second opening part from the first opening part.

9. The plastic film recovery device of claim 1, wherein the discharge part comprises:
a first body connected to the second opening part of the transfer part and comprising the plurality of holes; and
a second body connected to the first body in the first direction and comprising an outlet through which the cover plastic film transferred from the first body is discharged to outside of the discharge part.

10. The plastic film recovery device of claim 1, wherein a first cross-sectional area of the discharge part connected to the second opening part at a first point is greater than a third cross-sectional area of the discharge part at a third point between the first point and a second point where the cover plastic film is discharged.

11. The plastic film recovery device of claim 10, wherein a second cross-sectional area of the discharge part at the second point is greater than the third cross-sectional area at the third point of the discharge part.

12. The plastic film recovery device of claim 10, wherein a second cross-sectional area of the discharge part at the second point corresponds to the first cross-sectional area of the discharge part at the first point.

13. The plastic film recovery device of claim 10,
wherein the plurality of holes are positioned in the third point.

14. The plastic film recovery device of claim 1,
wherein the plastic film recovery device is disposed between two mounters,
wherein the plastic film recovery device further comprises:
a second suction part introducing the cover plastic film of the reel tape supplied to a first mounter disposed on one side of the film recovery device of the two mounters, and
wherein the first suction part introduces the cover plastic film of the reel tape supplied to a second mounter disposed on another side of the film recovery device of the two mounters.

15. The plastic film recovery device of claim 14,
wherein the transfer part further comprises a third opening part connected to the second suction part, and
wherein the first opening part is connected to the first suction part.

16. The plastic film recovery device of claim 15, wherein the second opening part is disposed between the first opening part and the second opening part.

17. The plastic film recovery device of claim 15, wherein the first nozzle is disposed between the first opening part and the third opening part.

18. The plastic film recovery device of claim 1, further comprising:
a control part operatively connected to the mounter,
wherein the control part is configured to:
operate the plastic film recovery device in response to identifying an operation of the mounter, and
interrupt an operation of the plastic film recovery device in response to identifying an interruption in the operation of the mounter.

19. A plastic film recovery device for recovering a cover plastic film of reel tape supplied to a mounter, the plastic film recovery device comprising:
a first suction part transferring the cover plastic film, which has been separated from the reel tape and introduced into one end of the first suction part to another end of the first suction part opposite to the one end, by forming internal pressure lower than external pressure;
a transfer part, the transfer part including:
a first opening part, connected to the other end of the first suction part, through which the cover plastic film is introduced from the other end, and
a second opening part through which the cover plastic film introduced through the first opening part flows out;
a first nozzle disposed inside the transfer part and ejecting air in a first direction facing the second opening part;
a discharge part connected to the second opening part in the first direction and discharging the cover plastic film transferred through the transfer part; and
a plurality of guides forming a vortex inside the discharge part by being disposed inside the discharge part to have an inclination with respect to the first direction.

20. The plastic film recovery device of claim 19, wherein the plurality of guides have the inclination with respect to a generatrix of the discharge part.
